(19) United States
(12) Patent Application Publication
(10) Pub. No.: US 2025/0377629 A1
(43) Pub. Date: Dec. 11, 2025

(54) HOLOGRAPHIC DISPLAY

(71) Applicant: Samsung Display Co., LTD., Yongin-si (KR)

(72) Inventors: Jong Cheon LEE, Yongin-si (KR); Soo Bin KIM, Yongin-si (KR); Yong Seok KIM, Yongin-si (KR); Ji Young NAM, Yongin-si (KR); Dong Chul SHIN, Yongin-si (KR); Hae Ju YUN, Yongin-si (KR)

(21) Appl. No.: 19/017,342

(22) Filed: Jan. 10, 2025

(30) Foreign Application Priority Data
Jun. 7, 2024 (KR) 10-2024-0074163

(51) Int. Cl. G03H 1/00; G02B 3/00; G02B 5/02; H04N 9/31

(52) U.S. Cl. CPC G03H 1/0005; G02B 3/0056; G02B 5/0278; H04N 9/3161; G03H 2001/0088

(57) ABSTRACT

A holographic display is provided. A holographic display includes, a first substrate, a first lens layer on one surface of the first substrate, a light source layer on an opposite surface of the first substrate, a second substrate on the first lens layer, a light modulation element on one surface of the second substrate, and a second lens layer on an opposite surface of the second substrate, wherein each of the first lens layer and the second lens layer includes a meta-lens.

### CROSS-REFERENCE TO RELATED APPLICATION

The present application claims priority to and the benefit of Korean Patent Application No. 10-2024-0074163, filed on Jun. 7, 2024, in the Korean Intellectual Property Office, the entire content of which is incorporated herein by reference.

### BACKGROUND

### 1. Field

Embodiments of the present disclosure relate to a holographic display.

### 2. Description of the Related Art

With the progression (advancement) of the information age, the demand for various forms (types) of display devices capable of presenting (displaying) images has surged (increased). Holographic displays (display devices), for instance, operate on the principle that an image of an original object is recreated when reference light is projected (irradiated) and diffracted into a hologram (e.g., holographic) pattern. This pattern records an interference pattern created by interaction of (interfering) the object light reflected from the original object with the reference light.

Additionally, research into holographic displays is actively ongoing. As a type (form) of digital holographic display, instead of directly exposing the original object to create (obtain) a holographic pattern, a computer generated hologram (CGH) is utilized (provided) as the electrical signal for a spatial light modulator. The spatial modulator diffracts reference light to form holographic patterns based on (according to) input CGH signals, thereby producing (generating) three-dimensional images. Active research is being conducted on such holographic displays.

The above information disclosed in this Background section is intended to enhance understanding of the background of the disclosure and may contain information that does not constitute prior art.

### SUMMARY

Aspects of one or more embodiments of the present disclosure are directed toward a compact holographic display enhanced or improved through thinning and integration.

Aspects of one or more embodiments of the present disclosure are directed toward a compact holographic display in which an optical member positioned between a light source panel and a spatial light modulator is miniaturized. For example, this involves miniaturizing a optical member positioned between a light source panel and a spatial light modulator.

Additional aspects will be set forth in part in the description which follows and, in part, will be apparent from the description, or may be learned by practice of the presented embodiments of the disclosure.

According to one or more embodiments of the present disclosure, a holographic display includes a first substrate, a first lens layer arranged on one surface of the first substrate, a light source layer arranged on the other (e.g., an opposite) surface of the first substrate, a second substrate arranged on the first lens layer, a light modulation element arranged on one surface of the second substrate, and a second lens layer arranged on the other (e.g., an opposite) surface of the second substrate, wherein each of the first lens layer and the second lens layer includes a meta-lens.

In one or more embodiments, the light source layer may include first to third laser elements spaced and/or apart (e.g., spaced apart or separated) from each other, and the first lens layer may include first to third diffusion meta-lenses that overlap the first to third laser elements, respectively.

In one or more embodiments, the first to third laser elements may respectively include first to third light emission areas through which light is to be emitted, and a width of the first to third diffusion meta-lenses may be larger than a width of each of the first to third light emission areas.

In one or more embodiments, the first to third diffusion meta-lenses may be configured to diffuse incident light.

In one or more embodiments, the first to third diffusion meta-lenses may include a diffusion type (kind) lens.

In one or more embodiments, the first to third diffusion meta-lenses may include a convergent lens.

In one or more embodiments, the second lens layer may include a collimation meta-lens, and the collimation meta-lens may be configured to convert incident light into parallel light.

In one or more embodiments, the light source layer may include at least one laser element, and the laser element may be a vertical cavity surface emitting laser (VCSEL).

In one or more embodiments, the laser element may include a first electrode arranged on the other (e.g., an opposite) surface of the first substrate, a first reflective layer arranged on the first electrode, an opening layer arranged on the first reflective layer, an active layer arranged on the opening layer, a second reflective layer arranged on the active layer, and a second electrode arranged on the second reflective layer.

In one or more embodiments, the laser element may further include a passivation layer arranged on the second electrode, the passivation layer including (defining) an opening exposing at least a portion of a lower surface of the second electrode, and the light source layer may further include a reflective electrode covering the laser element, the reflective electrode arranged on the passivation layer.

In one or more embodiments, the at least one laser element may include a first laser element, a second laser element and/or a third laser element, and the first electrode may be commonly arranged (located) over the first to third laser elements.

In one or more embodiments, the light modulation element may include a circuit layer, a liquid crystal element layer arranged on the circuit layer, and a color filter layer arranged on the liquid crystal element layer.

In one or more embodiments, the first lens layer may be configured to diffuse light passing through the first lens layer, and the second lens layer may be configured to convert the diffused light passing through the second lens layer into parallel light. For example, the first lens layer may be configured to diffuse light passing through it, and the second lens layer may be configured to convert the diffused light passing through it into parallel light.

According to one or more embodiments of the present disclosure, a holographic display includes a light source panel including a light source layer and a first lens layer arranged on the light source layer, and a spatial light modulator arranged on the light source panel, the spatial light modulator including a second lens layer and a light modulation element arranged on the second lens layer, wherein each of the first lens layer and the second lens layer includes a meta-lens.

In one or more embodiments, the light source panel may include one or more light source pixels to emit light, the spatial light modulator may include a plurality of light modulation pixels to modulate a phase of light, and the number of the light modulation pixels may be greater than the number of the light source pixels.

In one or more embodiments, the light source pixels may include first to third light source pixels, and the first to third light source pixels may be configured to emit light incident on all of the light modulation pixels. For example, these light source pixels may be configured to emit light that is incident on all of the light modulation pixels.

In one or more embodiments, a size of the light source panel may be smaller than a size of the spatial light modulator.

In one or more embodiments, the holographic display may further include a sealing portion sealing a space between the light source panel and the spatial light modulator, and a gap defined by the light source panel, the spatial light modulator and the sealing portion, wherein the first lens layer and the second lens layer may be arranged in (inside) the gap.

In one or more embodiments, a height of the gap may be in a range of 5 mm to 20 mm.

In one or more embodiments, a size of the meta-lens of the first lens layer may be smaller than a size of the meta-lens of the second lens layer.

According to one or more embodiments of the present disclosure, an electronic device includes a holographic device including a first substrate; a first lens layer on one surface of the first substrate; a light source layer on an opposite surface of the first substrate; a second substrate on the first lens layer; a light modulation element on one surface of the second substrate; and a second lens layer on an opposite surface of the second substrate, wherein each of the first lens layer and the second lens layer comprises a meta-lens.

According to one or more embodiments of the present disclosure, a compact holographic display may be improved through thinning and integration.

According to the holographic display of one or more embodiments of the present disclosure, an optical member positioned between a light source panel and a spatial light modulator may be miniaturized.

The effects according to one or more embodiments of the present disclosure are not limited to those mentioned above and one or more suitable effects may be included in the following description of the present disclosure.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a holographic display according to one or more embodiments of the present disclosure;

FIG. 2 is an exploded perspective view illustrating a holographic display according to one or more embodiments of the present disclosure;

FIG. 3 is a plan view illustrating a holographic display viewed from a rear surface, according to one or more embodiments of the present disclosure;

FIG. 4 is a schematic cross-sectional view illustrating a holographic display according to one or more embodiments of the present disclosure;

FIG. 5 is a schematic cross-sectional view illustrating a holographic display according to one or more embodiments of the present disclosure;

FIG. 6 is a schematic diagram illustrating a spatial light modulator according to one or more embodiments of the present disclosure;

FIG. 7 is a plan view illustrating a first lens layer according to one or more embodiments of the present disclosure;

FIG. 8 is a plan view illustrating a second lens layer according to one or more embodiments of the present disclosure;

FIG. 9 is a schematic view illustrating a path of light emitted from a light source layer according to one or more embodiments of the present disclosure;

FIG. 10 is a schematic view illustrating a path of light emitted from a light source layer according to one or more embodiments of the present disclosure;

FIG. 11 is a plan view illustrating a nano pattern according to one or more embodiments of the present disclosure; and

FIG. 12 is a plan view illustrating a nano pattern according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

e.g. Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Hereinafter, embodiments of the present disclosure will be described in more detail with reference to the accompanying drawings.

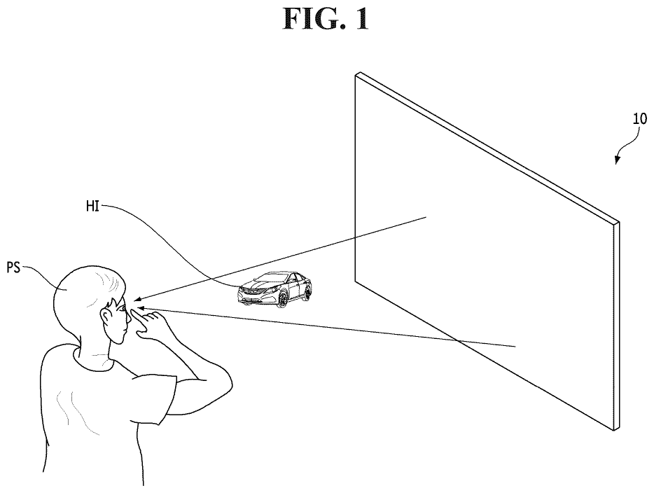

FIG. 1 is a perspective view illustrating a holographic display according to one or more embodiments of the present disclosure.

Referring to FIG. 1, a holographic display 10 according to one or more embodiments may reproduce an image of an original object by irradiating and diffracting reference light into a hologram (e.g., holographic) pattern in which an interference pattern is obtained by interfering object light reflected from the original object with the reference light. For example, the holographic display 10 may generate and reproduce a holographic image HI of a three-dimensional shape.

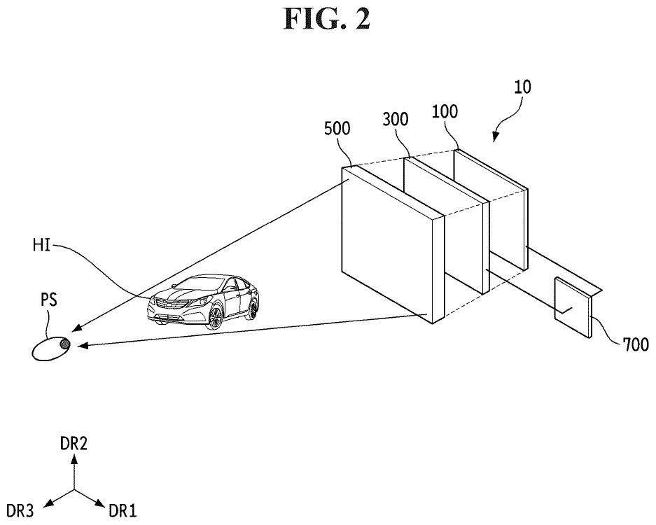

In one or more embodiments, the holographic display 10 may generate a holographic image HI by using information on an object digitized through a computer, instead of a real original object. For example, a computer generated hologram (CGH) generated by a holography generator 700 (see, e.g., FIG. 2) is provided to a spatial light modulator 300 (see, e.g., FIG. 2) as an electrical signal, and the spatial light modulator 300 (see, e.g., FIG. 2) may generate a holographic image HI by diffracting the reference light based on the computer generated hologram (CGH).

Because the holographic image HI generated by the holographic display 10 according to one or more embodiments is formed three-dimensionally in a three-dimensional space by using the interference of light, a user PS may view the holographic image HI with a naked eye without wearing separate glasses or head mounted display (HMD).

The holographic display 10 according to one or more embodiments of the present disclosure may be applied to portable electronic devices such as mobile phones, smartphones, tablet personal computers (PCs), mobile communication terminals, electronic notebooks, electronic books, portable multimedia players (PMPs), navigation devices, and/or ultra-mobile PCs (UMPCs). Alternatively, the holographic display 10 according to one or more embodiments may be applied as a display unit of a television, a notebook computer, a monitor, a billboard, and/or an Internet of things (IoT) device. Alternatively, the holographic display 10 according to one or more embodiments may be applied to wearable devices such as smart watches, and/or watch phones. Alternatively, the holographic display 10 according to one or more embodiments may be applied to a car display, such as a display in a dashboard of a vehicle, a center fascia of a vehicle, a center information display (CID) arranged on a dashboard of a vehicle, a room mirror display replacing side mirrors of a vehicle, and/or a display arranged on the back of a front seat as an entertainment for rear-seat passengers of a vehicle.

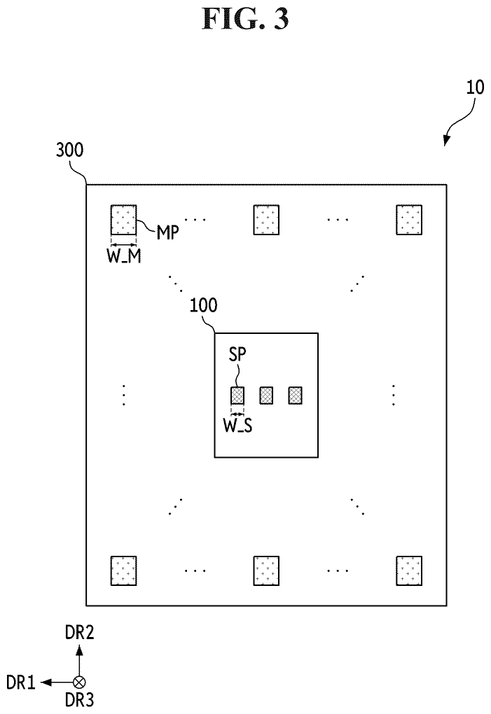

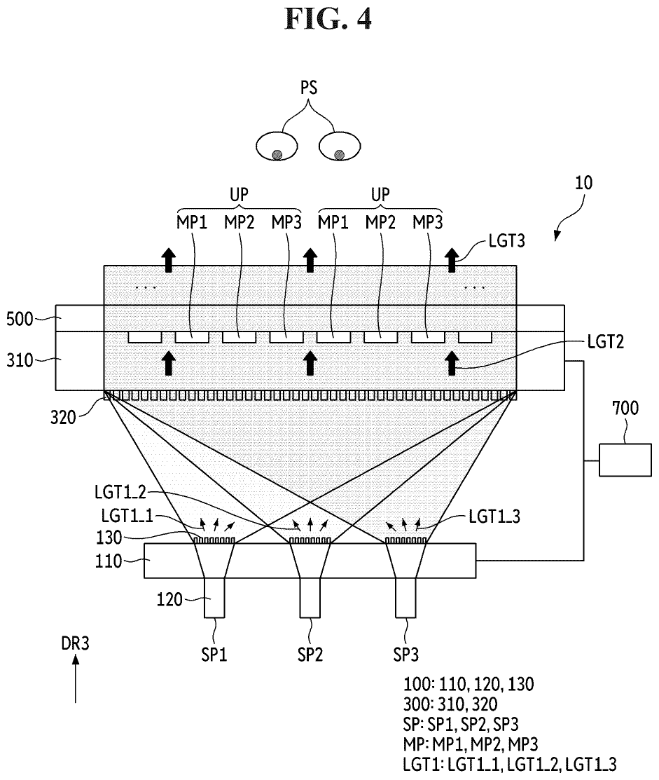

FIG. 2 is an exploded perspective view illustrating a holographic display according to one or more embodiments of the present disclosure. FIG. 3 is a plan view illustrating a holographic display, which is viewed from a rear surface, according to one or more embodiments of the present disclosure. FIG. 4 is a schematic cross-sectional view illustrating a holographic display according to one or more embodiments of the present disclosure.

Referring to FIGS. 2 to 4, the holographic display 10 according to one or more embodiments may include a light source panel 100, a spatial light modulator 300, an optical member 500, and a holography generator 700.

The light source panel 100 may be to emit light toward a surface directed toward the user PS. For example, the light source panel 100 may be to emit light in a third direction DR3.

In the drawings, the third direction DR3 may refer to a thickness direction of the holographic display 10. The third direction DR3 may be a vertical direction. First and second directions DR1 and DR2 may cross the third direction DR3, and for example, may be horizontal directions orthogonal to the third direction DR3. The first and second directions DR1 and DR2 are horizontal directions, which cross each other, and for example, the first and second directions DR1 and DR2 may be orthogonal to each other. Unless defined otherwise, in the present disclosure, directions indicated by arrows in the first to third directions DR1, DR2 and DR3 may be referred to as one side, and opposite directions thereof may be referred to as the other side.

The light source panel 100 may have a planar shape or a plate shape, which extends in a direction normal (e.g., perpendicular) to the thickness direction of the holographic display 10. For example, the light source panel 100 may extend in a horizontal direction normal (e.g., perpendicular) to the third direction DR3, for example, in the first direction DR1 and the second direction DR2. A thickness of the light source panel 100, for example, a length of the light source panel 100 in the third direction DR3, may be smaller than a length of the light source panel 100 in the horizontal direction, for example, in the first direction DR1 and the second direction DR2.

The light source panel 100 may include a coherent light source. For example, the light source panel 100 may be to emit a coherent beam. In one or more embodiments, the light source panel 100 may include a laser as a coherent light source for emitting a coherent beam.

The light source panel 100 may include light source pixels SP spaced and/or apart (e.g., spaced apart or separated) from each other in a horizontal direction. The light source pixel SP may be to emit light in the third direction DR3.

At least one light source pixel SP may be provided. In one or more embodiments, the light source pixel SP may include a first light source pixel SP1, a second light source pixel SP2 and a third light source pixel SP3. The first to third light source pixels SP1, SP2 and SP3 may be spaced and/or apart (e.g., spaced apart or separated) from one another in the first direction DR1 or the second direction DR2. For example, as shown in FIG. 4, the first to third light source pixels SP1, SP2 and SP3 may be spaced and/or apart (e.g., spaced apart or separated) from one another in the first direction DR1.

The first to third light source pixels SP1, SP2 and SP3 may be to emit light of different colors. For example, the first light source pixel SP1 may be to emit red light, the second light source pixel SP2 may be to emit green light, and the third light source pixel SP3 may be to emit blue light. For example, the blue light may indicate that a main peak wavelength is included in a wavelength band of 370 nm to 460 nm, approximately (e.g., about 370 nm to about 460 nm), the green light may indicate that a main peak wavelength is included in a wavelength band of 480 nm to 560 nm, approximately (e.g., about 480 nm to about 560 nm), and the red light may indicate that a main peak wavelength is included in a wavelength band of 600 nm to 750 nm, approximately (e.g., about 600 nm to about 750 nm).

The light source pixel SP is shown as including three types (kinds) of pixels that emit light of different colors, but the present disclosure is not limited thereto. In one or more embodiments, the light source pixel SP may include pixels less than or more than three.

The light source panel 100 may individually adjust the intensity of light emitted from the light source pixel SP. Therefore, the light source panel 100 may individually adjust the amplitude of light emitted from the light source pixel SP.

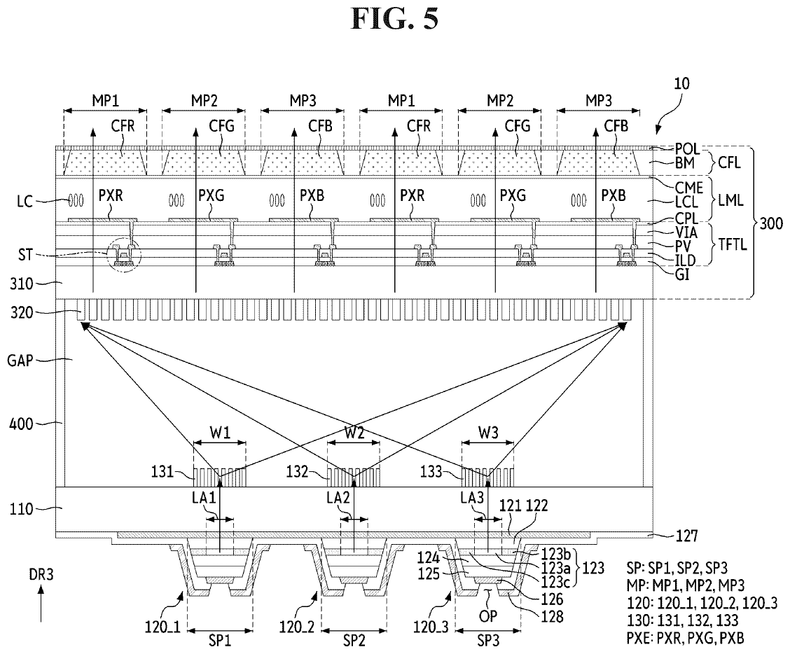

The light source panel 100 may include a first substrate 110, a light source layer 120 arranged on one surface of the first substrate 110, and a first lens layer 130 arranged on the other (e.g., opposite) surface of the first substrate 110. The light source layer 120 may be to emit a coherent beam. The first lens layer 130 may diffuse light incident from the light source layer 120. A detailed structure of the light source panel 100 will be described in more detail later with reference to FIG. 5.

The spatial light modulator 300 may be arranged on one surface of the light source panel 100. For example, the spatial light modulator 300 may be arranged on one side of the light source panel 100 in the third direction DR3. The spatial light modulator 300 may be arranged on a display surface or a light emitting surface of the light source panel 100. The one surface of the light source panel 100, on which the spatial light modulator 300 is arranged, may be a surface directed toward the user PS. The spatial light modulator 300 may be positioned between the light source panel 100 and the user PS.

The spatial light modulator 300 may have a planar shape or a plate shape, which extends in a direction normal (e.g., perpendicular) to the thickness direction of the holographic display 10. For example, the spatial light modulator 300 may extend in a horizontal direction normal (e.g., perpendicular) to the third direction DR3, for example, in the first direction DR1 and the second direction DR2. A thickness of the spatial light modulator 300, for example, a length of the spatial light modulator 300 in the third direction DR3, may be smaller than a length of the spatial light modulator 300 in the horizontal direction, for example, in the first direction DR1 and the second direction DR2.

The holographic display 10 according to one or more embodiments may be thinned (e.g., easily thinned) as the planar or plate-shaped spatial light modulator 300 is attached to the planar or plate-shaped light source panel 100.

The spatial light modulator 300 may include a plurality of light modulation pixels MP arranged to be spaced and/or apart (e.g., spaced apart or separated) from each other in the horizontal direction. Each of the plurality of light modulation pixels MP may be to transmit light emitted from the plurality of light source pixels SP in the third direction DR3. The light emitted from the plurality of light source pixels SP may be provided to the user PS by transmitting it through the plurality of light modulation pixels MP. The user PS may recognize the holographic image HI through the light transmitted through the spatial light modulator 300.

The plurality of light modulation pixels MP of the spatial light modulator 300 may individually adjust the phase or amplitude of the light emitted from the plurality of light source pixels SP of the light source panel 100. For example, the spatial light modulator 300 may generate the holographic image HI by individually adjusting the phase or amplitude of the light emitted from the plurality of light source pixels SP based on digital hologram pattern information provided from the holography generator 700.

The plurality of spatial light modulation pixels MP may include a first light modulation pixel MP1, a second light modulation pixel MP2 and a third light modulation pixel MP3. As shown in FIG. 3, the first to third light modulation pixels MP1, MP2 and MP3 may be spaced and/or apart (e.g., spaced apart or separated) from one another in the first direction DR1 and the second direction DR2.

The first to third light modulation pixels MP1, MP2 and MP3 may be to emit light of different colors. For example, the first light modulation pixel MP1 may be to emit red light, the second light source pixel SP2 may be to emit green light, and the third light source pixel SP3 may be to emit blue light.

The first to third light modulation pixels MP1, MP2 and MP3 may constitute one unit pixel UP. The unit pixel UP refers to a basic unit for displaying one color by combination of light emitted from the first to third light modulation pixels MP1, MP2 and MP3.

In one or more embodiments, as shown in FIG. 3, a size of the spatial light modulator 300 may be larger than that of the light source panel 100. For example, the spatial light modulator 300 may be approximately several millimeters to several centimeters and the light source panel 100 may be approximately several micrometers, but the present disclosure not limited thereto. In one or more embodiments, the light source panel 100 may be arranged to be approximately adjacent to the center of the spatial light modulator 300. Therefore, only a portion of the spatial light modulator 300 may overlap the light source panel 100 in the third direction DR3, and the other portion thereof may not overlap the light source panel 100.

The light emitted from the light source pixel SP may be diffused by the first lens layer 130, which will be described in more detail later, to reach the plurality of light modulation pixels MP arranged in the spatial light modulator 300. For example, in the holographic display 10 according to one or more embodiments, even though the size of the light source panel 100 is small, the light emitted from the light source pixel SP and diffused by the first lens layer 130 may reach all the light modulation pixels MP of the spatial light modulator 300. Therefore, the size of the light source panel 100 may be manufactured to be more compact, and the number of light sources included in the light source panel 100 may be reduced.

In one or more embodiments, as shown in FIG. 3, a size or area of the light modulation pixel MP may be greater than that of the light source pixel SP. For example, a width W_M of the light modulation pixel MP may be greater than a width W_S of the light source pixel SP. The width W_M of the light modulation pixel MP may be approximately hundreds of nanometers and the width W_S of the light source pixel

SP may be approximately several tens of nanometers, but the present disclosure is not limited thereto. Also, the number of light modulation pixels MP may be greater than the number of light source pixels SP.

In one or more embodiments, the spatial light modulator 300 may be a transmissive spatial light modulator 300. For example, a liquid crystal spatial light modulator (LC-SLM) and/or the like may be used as the spatial light modulator 300. In the present disclosure, the spatial light modulator 300 will be described as being a liquid crystal spatial light modulator by way of example, but the present disclosure is not limited thereto.

The spatial light modulator 300 may include a second substrate 310 and a second lens layer 320 arranged on one surface of the second substrate 310. The second lens layer 320 may convert the diffused light incident from the light source panel 100 into parallel light. A detailed structure of the spatial light modulator 300 will be described in more detail later with reference to FIG. 5.

The optical member 500 may be arranged on one surface of the spatial light modulator 300. For example, the optical member 500 may be arranged on one side of the spatial light modulator 300 in the third direction DR3. The optical member 500 may be arranged on a light emitting surface of the spatial light modulator 300. The one surface of the spatial light modulator 300, on which the optical member 500 is arranged, may be a surface directed toward the user PS. The optical member 500 may be positioned between the spatial light modulator 300 and the user PS.

The optical member 500 may adjust a size and a shape of an image such as by enlarging or downsizing the holographic image HI by adjusting the light transmitted from the spatial light modulator 300. For example, the optical member 500 may include one or more suitable lenses such as a convex lens, a concave lens, a cylindrical lens, a compound lens, a Fresnel lens, an anamorphic lens and/or a meniscus lens, but the present disclosure is not limited thereto. The optical member 500 may include other members such as a mirror.

The holography generator 700 may generate a computer generated hologram (CGH). The computer generated hologram is a hologram pattern, and may include information on the amplitude and phase of light for generating the holographic image HI.

The holography generator 700 may generate a hologram pattern by providing information on the amplitude and phase of light emitted from the light source pixels SP of the light source panel 100. The holography generator 700 may provide a hologram pattern, in which information on the amplitude and phase of the light emitted from the light source pixels SP of the light source panel 100 is reflected, to the spatial light modulator 300. The spatial light modulator 300 may individually adjust a phase of light in accordance with the amplitude and phase of the light reflected in the holographic pattern.

According to the holographic display 10 of one or more embodiments, first light LGT1 emitted from the light source pixel SP of the light source panel 100 may be diffused through the first lens layer 130. The diffused first light LGT1 may be converted into second light LGT2, which is parallel light, through the second lens layer 320 of the spatial light modulator 300. For example, the second light LGT2 may be the parallel light which moves in the third direction DR3. The second light LGT2 may be converted into third light LGT3 by modulation of the phase or amplitude in the light modulation pixel MP of the spatial light modulator 300. The user PS may visually recognize the holographic image HI through the third light LGT3.

The holographic display 10 according to one or more embodiments may be driven in a space division mode or a time division mode to prevent or reduce color mixture of light emitted from the unit pixel UP and to increase a color reproduction rate. For example, if (e.g., when) the holographic display 10 is driven in the space division mode, the first to third light modulation pixels MP may include color filters CFR, CFG and CFB (see, e.g., FIG. 5) that transmit light of different colors. For another example, if (e.g., when) the holographic display 10 is driven in the time division mode, the first to third light source pixels SP may be to emit light at different frames with a time difference. For example, the first light LGT1 may include first sub-light LGT1_1 that emits light from a first light source pixel SP1, second sub-light LGT1_2 that emits light from a second light source pixel SP2 and third sub-light LGT1_3 that emits light from a third light source pixel SP3, and the first to third sub-lights LGT1_1, LGT1_2 and LGT1_3 may be emitted at different times or in different frames. In the present disclosure, the holographic display 10 will be described as being driven in the space division mode by way of example, but the present disclosure is not limited thereto.

Hereinafter, a detailed structure of the holographic display 10 will be described in more detail with reference to FIG. 5.

FIG. 5 is a cross-sectional view illustrating a holographic display according to one or more embodiments of the present disclosure.

Referring to FIG. 5 in addition to FIGS. 3 and 4, the holographic display 10 may include a light source panel 100, a spatial light modulator 300 and a sealing portion 400.

The light source panel 100 may include a first substrate 110, a light source layer 120 and a first lens layer 130.

The first substrate 110 may support the light source layer 120 and the first lens layer 130. The first substrate 110 may include a transparent material having high transmittance to allow light emitted from the light source layer 120 to pass therethrough. In one or more embodiments, the first substrate 110 may include glass that is rigid. In one or more embodiments, the first substrate 110 may include an insulating material of a polymer resin such as polyimide, which has a flexible property capable of being subjected to bending, folding, rolling and/or the like. In one or more embodiments, the first substrate 110 may include a group III-V compound semiconductor crystal such as gallium phosphide (GaP), aluminum gallium arsenide (AlGaAs) and/or gallium nitride (GaN), a group II-VI semiconductor crystal such as zinc sulfide (ZnS) and/or zinc selenide (ZnSe), and/or a group IV semiconductor crystal such as hexagonal or cubic carbide (SiC).

The light source layer 120 may be arranged on the other surface (for example, on a lower surface as shown, for example, in FIG. 5, that is opposite the upper surface) of the first substrate 110. The light source layer 120 may include a coherent light source. The light source layer 120 is a surface light emitting element, and may include a vertical cavity surface emitting laser (VCSEL). For example, the light source layer 120 may include a first laser element 120_1 arranged in the first light source pixel SP1, a second laser element 120_2 arranged in the second light source pixel SP2, and a third laser element 120_3 arranged in the third light source pixel SP3. The first to third laser elements 120_1, 120_2 and 120_3 may be arranged to be spaced and/or apart (e.g., spaced apart or separated) from one another.

Each of the first to third laser elements 120_1, 120_2 and 120_3 of the light source layer 120 may include a first electrode 121, a first reflective layer 122, an opening layer 123, an active layer 124, a second reflective layer 125, a second electrode 126, and a passivation layer 127.

The first electrode 121 may be arranged on the other surface of the first substrate 110. The first electrode 121 may be arranged over the first to third light source pixels SP1, SP2 and SP3. The first electrode 121 may be arranged over the first to third laser elements 120_1, 120_2 and 120_3. The first electrode 121 may be a common electrode of the first to third laser elements 120_1, 120_2 and 120_3.

The first electrode 121 may be a cathode electrode of the first to third laser elements 120_1, 120_2 and 120_3, but the present disclosure is not limited thereto, and the first electrode 121 may be also an anode electrode. The first electrode 121 may include a conductive material such as metal. For example, the first electrode 121 may include at least one of aluminum (Al), titanium (Ti), chromium (Cr), nickel (Ni), copper (Cu) or gold (Au) to form a single-layered structure or a multi-layered structure.

The first reflective layer 122 may be arranged on the first electrode 121. The first reflective layer 122 may include a gallium-based compound, for example, aluminum gallium arsenide (AlGaAs), but the present disclosure is not limited thereto. The first reflective layer 122 may be a distributed Bragg reflector (DBR). For example, the first reflective layer 122 may have a structure in which first and second layers made of materials having different refractive indexes are alternately stacked at least once or more.

The first layer and the second layer may adjust a refractive index by adjusting a ratio of aluminum (Al) and gallium (Ga), which are contained in AlGaAs. For example, if (e.g., when) the ratio (proportion) of aluminum (Al) is increased, the refractive index of the first layer and/or the second layer may be reduced, and if (e.g., when) the ratio (proportion) of gallium (Ga) is increased, the refractive index of the first layer and/or the second layer may be increased.

The first reflective layer 122 may be doped with a first conductivity type (kind). For example, the first conductivity type (kind) dopant may include an n-type (kind) dopant such as silicon (Si), germanium (Ge), tin (Sn), selenium (Se) and/or tellurium (Te).

The opening layer 123 may be arranged on the first reflective layer 122. The opening layer 123 may include an opening 123a, a first insulating area 123b and a second insulating area 123c.

The first insulating area 123b and the second insulating area 123c may be arranged on one side and the other side (e.g., on opposite sides) of the opening 123a, but the present disclosure is not limited thereto. The first insulating area 123b and the second insulating area 123c may be integrally formed and arranged to be around (e.g., surround) the opening 123a on a plane. In one or more embodiments, the first insulating area 123b and the second insulating area 123c may include aluminum oxide, but the present disclosure is not limited thereto.

The opening 123a may be defined by the first insulating area 123b and the second insulating area 123c. For example, the opening 123a may be a portion of the opening layer 123, in which the first insulating area 123b and the second insulating area 123c are not arranged.

For example, if (e.g., when) the opening layer 123 includes aluminum gallium arsenide (AlGaAs), as aluminum gallium arsenide (AlGaAs) of the opening layer 123 reacts with water, an edge of the opening layer 123 is changed to aluminum oxide, so that the first insulating area 123b and the second insulating area 123c may be formed, and a central portion of the opening layer 123, which does not react with water, may be the opening 123a made of aluminum gallium arsenide (AlGaAs).

In one or more embodiments, light generated from the active layer 124 may move toward the first lens layer 130 through the opening 123a. Therefore, a light emission area may be defined in each of the first to third laser elements 120_1, 120_2 and 120_3. For example, an area that overlaps the opening 123a of the first laser element 120_1 may be a first light emission area LA1, an area that overlaps the opening 123a of the second laser element 120_2 may be a second light emission area LA2, and an area that overlaps the opening 123a of the third laser element 120_3 may be a third light emission area LA3.

The active layer 124 may be arranged on the opening layer 123. The active layer 124 may include any one of a single well structure, a multi-well structure, a single quantum well structure, a multi-quantum well (MQW) structure, a quantum dot structure and/or a quantum line structure. The active layer 124 may include a quantum well layer and/or a quantum wall layer, each of which include a compound semiconductor material of a Group III-V element. The quantum well layer may be made of a material having an energy band gap smaller than that of the quantum wall layer. For example, the active layer 124 may be formed in one to three pairs of InGaAs/AlxGaAs, AlGaInP/GaInP, AlGaAs/AlGaAs, AlGaAs/GaAs, and/or GaAs/InGaAs, but the present disclosure is not limited thereto. The active layer 124 may not be doped with a dopant.

In one or more embodiments, a first cavity and a second cavity may be

further arranged above and below the active layer 124, respectively. The first cavity and the second cavity may contain AlGaAs, but are not limited thereto. For example, each of the first cavity and the second cavity may include a plurality of layers containing AlGaAs.

The second reflective layer 125 may be arranged on the active layer 124. Like the first reflective layer 122, the second reflective layer 125 may include a gallium-based compound, for example, aluminum gallium arsenide (AlGaAs), but the present disclosure is not limited thereto. The second reflective layer 125 may be a distributed Bragg reflector (DBR). For example, the second reflective layer 125 may have a structure in which the first and second layers made of materials having different refractive indexes are alternately stacked at least once or more.

The first layer and the second layer may adjust a refractive index by adjusting a ratio of aluminum (Al) and gallium (Ga), which are contained in AlGaAs. For example, if (e.g., when) the ratio (proportion) of aluminum (Al) is increased, the refractive index of the first layer and/or the second layer may be reduced, and if (e.g., when) the ratio (proportion) of gallium (Ga) is increased, the refractive index of the first layer and/or the second layer may be increased.

The second reflective layer 125 may be doped with a second conductivity type (kind). For example, the second conductivity type (kind) dopant may include a p-type (kind) dopant such as magnesium (Mg), zinc (Zn), calcium (Ca), strontium (Sr) and/or barium (Ba).

The first reflective layer 122 and the second reflective layer 125 may have high reflectance with respect to light of a specific wavelength range. Therefore, light emitted from the active layer 124 may be continuously reflected between the first reflective layer 122 and the second reflective layer 125 to induce stimulus emission (stimulated emission) of the laser to the active layer 124. In one or more embodiments, positions of the first reflective layer 122 and the second reflective layer 125 may be switched.

A portion of the light emitted from the active layer 124 may be repeatedly reflected from (between) the first reflective layer 122 and the second reflective layer 125 to induce stimulus emission (stimulated emission) of the active layer 124. The other portion of the light emitted from the active layer 124 may be emitted toward the first lens layer 130 through the opening 123a.

The second electrode 126 may be arranged on the second reflective layer 125. The second electrode 126 may be arranged in the first to third light source pixels SP1, SP2 and SP3, respectively. The second electrode 126 may be arranged in the first to third laser elements 120_1, 120_2 and 120_3, respectively. The first electrode 121 may be an individual electrode arranged in each of the first to third laser elements 120_1, 120_2 and 120_3.

The second electrode 126 may be an anode electrode of the first to third laser elements 120_1, 120_2 and 120_3, but the present disclosure is not limited thereto, and the second electrode 126 may be also a cathode electrode. The second electrode 126 may include a conductive material such as metal. For example, the second electrode 126 may include at least one of aluminum (Al), titanium (Ti), chromium (Cr), nickel (Ni), copper (Cu) or gold (Au) to form a single-layered structure or a multi-layered structure.

The passivation layer 127 may be arranged on the second electrode 126. The passivation layer 127 may cover an upper surface and sides of the first electrode 121, sides surface of the first reflective layer 122, sides of the opening layer 123, sides of the active layer 124, an upper surface and sides of the second reflective layer 125 and an upper surface and sides of the second electrode 126. The passivation layer 127 may include an opening OP that exposes at least a portion of a lower surface of the second electrode 126. The second electrode 126 may be in contact with an external line through the opening OP.

The passivation layer 127 may be an insulating layer. In one or more embodiments, the passivation layer 127 may be formed of a multi-layer in which one or more inorganic layers of a silicon nitride layer, a silicon oxynitride layer, a silicon oxide layer, a titanium oxide layer and/or an aluminum oxide layer are alternately stacked. In one or more embodiments, the passivation layer 127 may be formed of an organic layer such as an acrylic resin, an epoxy resin, a phenolic resin, a polyamide resin and/or a polyimide resin.

In one or more embodiments, the light source layer 120 may further include a reflective electrode 128. The reflective electrode 128 may be arranged on the passivation layer 127. The reflective electrode 128 may cover at least a portion of a lower surface and sides of each of the first to third laser elements 120_1, 120_2 and 120_3. The reflective electrodes 128 arranged on the first to third laser elements 120_1, 120_2 and 120_3, respectively, may be spaced and/or apart (e.g., spaced apart or separated) from one another, and may be independently arranged on the first to third laser elements 120_1, 120_2 and 120_3. The reflective electrode 128 may include an opening communicating with the opening OP of the passivation layer 127 to expose the lower surface of the second electrode 126.

The holographic display 10 according to the present embodiments includes the reflective electrode 128 covering the lower surface and the sides of each of the first to third laser elements 120_1, 120_2 and 120_3, so that the light emitted from the active layer 124 may be reflected by the reflective electrode 128 and return to the active layer 124 again to maximize or increase the oscillation and amplification of the laser. Therefore, energy efficiency of the light source layer 120 may be improved.

The first lens layer 130 may be arranged on one surface (e.g., the upper surface as shown, for example, in FIG. 5) of the first substrate 110. The first lens layer 130 may diffuse the light emitted from the light source layer 120. For example, as described above with reference to FIG. 4, the light source pixels SP may provide light to a large number of light modulation pixels MP. In contrast, as described above with reference to FIG. 3, because the size of the light source panel 100 is considerably smaller than the size of the spatial light modulator 300, the first lens layer 130 may diffuse light in order for the light emitted from the light source pixels SP to reach the plurality of light modulation pixels MP.

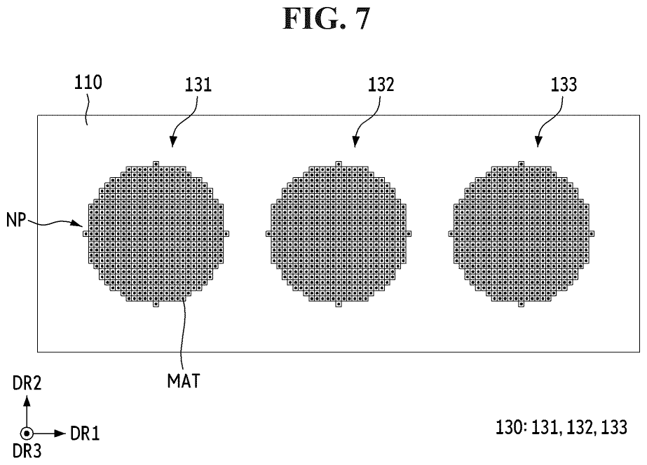

The first lens layer 130 may include a meta-lens. The meta-lens is a lens that includes a meta-surface to adjust a path of light, and a plurality of meta-atoms MAT (see, e.g., FIG. 7) may be arranged on the meta-surface to form a nano pattern NP (see, e.g., FIGS. 7, 11, and 12). The meta-atom MAT (see, e.g., FIG. 7) and the nano pattern NP (see, e.g., FIGS. 7, 11, and 12) of the first lens layer 130 will be described in more detail later with reference to FIGS. 7, 11 and 12.

The meta-lens of the first lens layer 130 may have a lens surface that is flat and thin without being convex or concave to adjust an angle of light so that the light may be focused on one focal point. A monochromatic aberration corrected meta-lens, an achromatic aberration corrected meta-lens, a sub-resolution meta-lens, a nonlinear meta-lens, a diffractive meta-lens, a dielectric meta-lens, and/or the like may be used as the meta-lens included in the first lens layer 130.

The first lens layer 130 may include a first diffusion meta-lens 131 that overlaps the first light source pixel SP1, a second diffusion meta-lens 132 that overlaps the second light source pixel SP2, and a third diffusion meta-lens 133 that overlaps the third light source pixel SP3.

A width of each of the meta-lenses 131, 132, 133 of the first lens layer 130 may be greater than that of each of the light source pixels SP and may be greater than that of each of the first to third light emission areas LA1, LA2 and LA3. For example, a width W1 of the first diffusion meta-lens 131 may be greater than the width of the first light source pixel SP1 and the first light emission area LA1, a width W2 of the second diffusion meta-lens 132 may be greater than the width of the second light source pixel

SP2 and the second light emission area LA2, and a width W3 of the third diffusion meta-lens 133 may be greater than the width of the third light source pixel SP3 and the third light emission area LA3.

The spatial light modulator 300 may be arranged on the light source panel 100. The spatial light modulator 300 may include a second substrate 310, a circuit layer TFTL, a liquid crystal element layer LML, a color filter layer CFL, a polarizing layer POL and a second lens layer 320.

The second substrate 310 may support the circuit layer TFTL and the second lens layer 320. The second substrate 310 may include a transparent material. For example, the second substrate 310 may include a transparent insulating material such as glass or quartz. The second substrate 310 may be a rigid substrate, but the present disclosure is not limited thereto. The second substrate 310 may include plastic such as polyimide, or may have a flexible property that may be curved, bent, folded or rolled.

The circuit layer TFTL may be arranged on one surface (e.g., the upper surface as shown, for example, in FIG. 5) of the second substrate 310. The circuit layer TFTL may include a transistor ST (e.g., a plurality of transistors), a gate insulating layer GI, an interlayer insulating layer ILD, a passivation layer PV, a via layer VIA and a capping layer CPL.

A transistor ST of the plurality of transistors ST may be arranged in each of the first light modulation pixel MP1, the second light modulation pixel MP2 and the third light modulation pixel MP3. Each transistor ST may include an active area, a gate electrode, a drain electrode and a source electrode. Each transistor ST may be connected to a pixel electrode PXE (of the plurality of pixel electrodes PXE) to adjust a behavior of liquid crystal molecules LC of the liquid crystal element layer LML.

The gate insulating layer GI may be arranged on the active areas of he transistors SP. The gate insulating layer GI may include an inorganic layer, for example, a silicon nitride layer, a silicon oxynitride layer, a silicon oxide layer, a titanium oxide layer and/or an aluminum oxide layer.

The interlayer insulating layer ILD may be arranged on the gate electrodes of the transistors SP. The interlayer insulating layer ILD may include an inorganic layer, for example, a silicon nitride layer, a silicon oxynitride layer, a silicon oxide layer, a titanium oxide layer and/or an aluminum oxide layer.

The passivation layer PV may be arranged on the drain electrodes and the source electrodes of the transistors SP. The passivation layer PV may include an inorganic layer, for example, a silicon nitride layer, a silicon oxynitride layer, a silicon oxide layer, a titanium oxide layer and/or an aluminum oxide layer.

The via layer VIA may be arranged on the passivation layer PV. The via layer VIA may include an organic layer such as an acrylic resin, an epoxy resin, a phenolic resin, a polyamide resin and/or a polyimide resin.

The capping layer CPL may be arranged on the via layer VIA. In one or more embodiments, the capping layer CPL may include an inorganic layer, for example, a silicon nitride layer, a silicon oxynitride layer, a silicon oxide layer, a titanium oxide layer and/or an aluminum oxide layer. In one or more embodiments, the capping layer CPL may include an organic layer such as an acryl resin, an epoxy resin, a phenol resin, a polyamide resin and/or a polyimide resin.

The liquid crystal element layer LML may be arranged on the capping layer CPL. The liquid crystal element layer LML may include the pixel electrodse PXE, a liquid crystal layer LCL and a common electrode CME.

The pixel electrodes PXE may be arranged on the capping layer CPL. The pixel electrodes PXE may be transmissive electrodes having high transmittance to visible light. In one or more embodiments, the pixel electrodes PXE may include a transparent conductive material such as indium tin oxide (ITO), indium zinc oxide (IZO) and/or zinc oxide (ZO).

The pixel electrodes PXE may include a first pixel electrode PXR, a second pixel electrode PXG and a third pixel electrode PXB. The first pixel electrode PXR may be arranged in the first light modulation pixel MP1. The second pixel electrode PXG may be arranged in the second light modulation pixel MP2. The third pixel electrode PXB may be arranged in the third light modulation pixel MP3. The pixel electrodes PXE may each be connected to one of the transistors ST through a contact hole.

The liquid crystal layer LCL may be arranged on the pixel electrodes PXE. The liquid crystal layer LCL may include liquid crystal molecules LC. The liquid crystal molecules LC may have dielectric anisotropy.

The common electrode CME may be arranged on the liquid crystal layer LCL. The common electrode CME may be a transmissive type (kind) electrode having high transmittance to visible light. In one or more embodiments, the common electrode CME may include a transparent conductive material such as indium tin oxide (ITO), indium zinc oxide (IZO) and/or zinc oxide (ZO). The common electrode CME may be an integrated electrode arranged over several light modulation pixels MP regardless of the distinction between the light modulation pixels MP.

In one or more embodiments, the liquid crystal element layer LML may further include an alignment layer arranged between the pixel electrodes PXE and the liquid crystal layer LCL and/or between the liquid crystal layer LCL and the common electrode CME.

In the present disclosure, the liquid crystal element layer LML has a structure in which the pixel electrodes PXE, the liquid crystal layer LCL and the common electrode CME are sequentially stacked, but the present disclosure is not limited thereto. For example, the liquid crystal element layer LML may have a structure in which the pixel electrodes PXE, the common electrode CME and the liquid crystal layer LCL are sequentially stacked or a structure in which the pixel electrodes PXE and the common electrode CME are arranged on the same layer.

The color filter layer CFL may be arranged on the liquid crystal element layer LML. The color filter layer CFL may include a plurality of color filters CFR, CFG and CFB respectively corresponding to the plurality of light modulation pixels MP1, MP2, and MP3, and a light blocking member BM arranged between the plurality of color filters CFR, CFG and CFB. Each of the color filters CFR, CFG and CFB may selectively transmit light of a specific wavelength (or in a specific wavelength range) and block or absorb light of other wavelengths.

The color filters CFR, CFG and CFB may include a first color filter CFR, a second color filter CFG and a third color filter CFB. The first color filter CFR may be arranged in the first light modulation pixel MP1, the second color filter CFG may be arranged in the second light modulation pixel MP2, and the third color filter CFB may be arranged in the third light modulation pixel MP3.

The first color filter CFR may selectively transmit red light and block or absorb green light and blue light. For example, the first color filter CFR may be a red color filter, and may include a red colorant. The second color filter CFG may selectively transmit green light and block or absorb red light and blue light. For example, the second color filter CFG may be a green color filter, and may include a green colorant. The third color filter CFB may selectively transmit blue light and block or absorb red light and green light. For example, the third color filter CFB may be a blue color filter, and may include a blue colorant.

The light blocking member BM may be arranged between the color filters CFR, CFG and CFB. The light blocking member BM may include a light absorbing material. For example, the light blocking member BM may include an inorganic black pigment, an organic black pigment or an organic blue pigment. The inorganic black pigment may be a metal oxide such as carbon black or titanium black, the organic black pigment may include at least one of lactam black, perylene black or aniline black, and the organic blue pigment may be C.I. pigment blue, but the present disclosure is not limited thereto. The light blocking member BM may prevent or reduce the likelihood of visible light permeating between adjacent light modulation pixels MP to prevent or reduce the likelihood of color mixture occurring, thereby improving a color reproduction rate of the holographic display 10.

The polarizing layer POL may be arranged on the color filter layer CFL. The polarizing layer POL may linearly polarize unpolarized light. For example, the polarizing layer POL may be to transmit only light linearly polarized to be parallel with a polarizing axis. In one or more embodiments, the polarizing layer POL may not be provided.

The spatial light modulator 300 may adjust the phase of light by adjusting the behavior of the liquid crystal molecules LC of the liquid crystal element layer LML. Therefore, the holographic display 10 may generate the holographic image HI.

The second lens layer 320 may be arranged on the other surface (for example, the lower surface, as shown in, e.g., FIG. 5, that is opposite the upper surface) of the second substrate 310. The second lens layer 320 may convert the diffused light, which has passed through the first lens layer 130, into parallel light. For example, the second lens layer 320 may be inclined at a certain angle in the third direction DR3 to adjust the path of light so that incident light may move in the third direction DR3. Therefore, the parallel light moving in the third direction DR3 may be incident on the liquid crystal element layer LML.

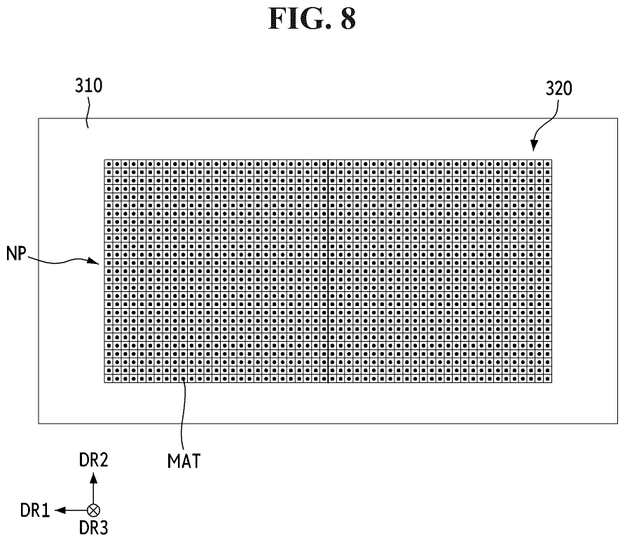

The second lens layer 320 may include a meta-lens. Like the meta-lens of the first lens layer 130, the meta-lens of the second lens layer 320 is a lens that includes a meta-surface to adjust a path of light, and a plurality of meta-atoms MAT (see, e.g., FIG. 78) may be arranged on the meta-surface to form a nano pattern NP (see, e.g., FIGS. 8, 11, and 12). The meta-atom MAT (see, e.g., FIG. 8) and the nano pattern NP (see, e.g., FIGS. 8, 11, and 12) of the second lens layer 320 will be described in more detail later with reference to FIGS. 8, 11, and 12.

The meta-lens of the second lens layer 320 may have a lens surface that is flat and thin without being convex or concave to adjust an angle of light so that the light may be focused on one focal point. A monochromatic aberration corrected meta-lens, an achromatic aberration corrected meta-lens, a sub-resolution meta-lens, a nonlinear meta-lens, a diffractive meta-lens, a dielectric meta-lens, and/or the like may be used as the meta-lens included in the second lens layer 320.

In one or more embodiments, the second lens layer 320 may include a different type (kind) of meta-lens from the first lens layer 130. For example, unlike the first lens layer 130 including the diffusion meta-lens, the second lens layer 320 may include a collimating meta-lens.

The diffusion meta-lens of the first lens layer 130 and the collimating meta-lens of the second lens layer 320 will be described in more detail later with reference to FIGS. 7 and 8.

The sealing portion 400 may be arranged between the light source panel 100 and the spatial light modulator 300. The sealing portion 400 may partition a gap GAP by sealing (e.g., hermetically sealing) a space between the light source panel 100 and the spatial light modulator 300. For example, the gap GAP may be a closed space formed by the light source panel 100, the spatial light modulator 300 and the sealing portion 400. The first and second lens layers 130 and 320 may be positioned in the gap GAP. The gap GAP may be a vacuum, but the present disclosure is not limited thereto, and may also include a medium having high transmittance. In one or more embodiments, a height of the gap GAP, that is, a distance between the first and second lens layers 130 and 320 may be approximately 5 mm to 20 mm (e.g., about 5 mm to about 20 mm).

The holographic display 10 according to the present embodiments may become compact as each of the first lens layer 130 and the second lens layer 320 includes a meta-lens. For example, the meta-lens may adjust the path of light to a higher degree than a general lens, thereby minimizing or reducing the size of the light source layer 120. In addition, because the meta-lens may adjust the path of light even without having a convex or concave shape, the distance between the light source panel 100 and the spatial light modulator 300 may be more compact.

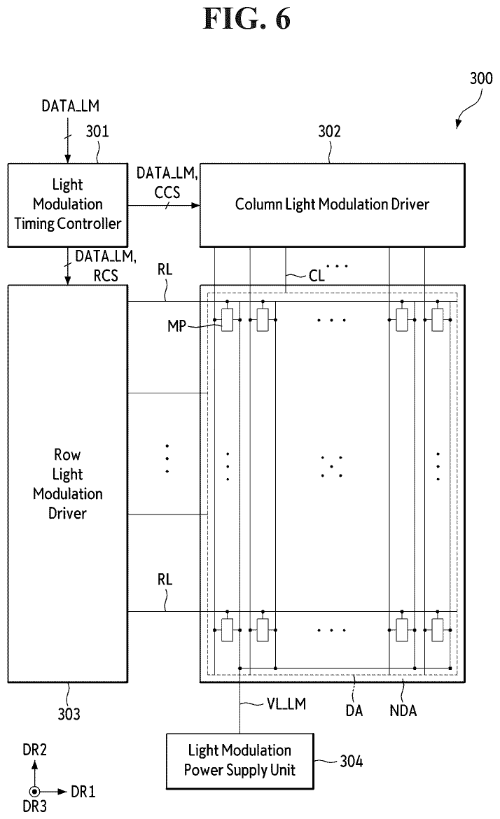

FIG. 6 is a plan view illustrating a spatial light modulator 300 according to one or more embodiments of the present disclosure.

Referring to FIG. 6 in addition to FIGS. 2 and 5, the spatial light modulator 300 may include a display area DA and a non-display area NDA. The display area DA may be arranged at an approximate center of the spatial light modulator 300, and the non-display area NDA may be arranged to be around (e.g., surround) the display area DA.

The display area DA of the spatial light modulator 300 may include a plurality of light modulation pixels MP, a plurality of light modulation power lines VL_LM connected to the plurality of light modulation pixels MP, a plurality of row-axis light modulation data lines RL, and a plurality of column-axis light modulation data lines CL.

The plurality of light modulation pixels MP may be arranged in the first direction DR1 and the second direction DR2. For example, the plurality of light modulation pixels MP may be arranged in a matrix along the first and second directions DR1, DR2. Each of the plurality of light modulation pixels MP may be connected to the plurality of light modulation power lines VL_LM, the plurality of row-axis light modulation data lines RL and the plurality of column-axis light modulation data lines CL. Each of the plurality of light modulation pixels MP may include at least one transistor ST, a light modulation element (e.g., the liquid crystal element layer LML as shown, for example, in FIG. 5) and a capacitor. In one or more embodiments, the capacitor may not be provided.

The row-axis light modulation data lines RL may extend in the first direction DR1, and may be spaced and/or apart (e.g., spaced apart or separated) from each other in the second direction DR2 crossing the first direction DR1. The row-axis light modulation data lines RL may sequentially supply row-axis light modulation data signals to the plurality of light modulation pixels MP.

The column-axis light modulation data lines CL may extend in the second direction DR2, and may be spaced and/or apart (e.g., spaced apart or separated) from each other in the first direction DR1. The column-axis light modulation data lines CL may supply column-axis light modulation data signals to the plurality of light modulation pixels MP.

The light modulation power lines VL_LM may extend in the second direction DR2, and may be spaced and/or apart (e.g., spaced apart or separated) from each other in the first direction DR1. The light modulation power line VL_LM may supply a power voltage to the plurality of light modulation pixels MP. The power voltage may be at least one of a driving voltage, a high potential voltage, an initialization voltage, a reference voltage, a bias voltage or a low potential voltage.

A light modulation timing controller 301 may receive light modulation digital data DATA_LM and timing signals from the holography generator 700. The light modulation timing controller 301 may generate a column-axis light modulation data control signal CCS and a row-axis light modulation data control signal RCS based on the timing signals. The light modulation timing controller 301 may control an operation timing of a column light modulation driver 302 by supplying the light modulation digital data DATA_LM and the column-axis light modulation data control signal CCS to the column light modulation driver 302. The light modulation timing controller 301 may control an operation timing of a row light modulation driver 303 by supplying the light modulation digital data DATA_LM and the row-axis light modulation data control signal RCS to the row light modulation driver 303.

The column light modulation driver 302 and the row light modulation driver 303 may convert the column-axis light modulation data control signal CCS and the row-axis light modulation data control signal RCS into analog light modulation data voltages, respectively, and may supply the data voltages to the column-axis light modulation data line CL and the row-axis light modulation data line RL.

The row light modulation driver 303 may be arranged on a left or right side of the non-display area NDA. The column light modulation driver 302 may be arranged on an upper or lower side of the non-display area NDA.

A light modulation power supply unit 304 may supply the power voltage to the spatial light modulator 300, the column light modulation driver 302 and the row light modulation driver 303. The light modulation power supply unit 304 may generate a driving voltage of the light modulation element and supply the generated driving voltage to a driving voltage line, generate an initialization voltage and supply the generated initialization voltage to an initialization voltage line, generate a bias voltage and supply the generated bias voltage to a bias voltage line and generate a low potential voltage and supply the generated low potential voltage to a low potential line.

FIG. 7 is a plan view illustrating a first lens layer 130 according to one or more embodiments of the present disclosure. FIG. 8 is a plan view illustrating a second lens layer 320 according to one or more embodiments of the present disclosure.

Referring to FIG. 7 in addition to FIG. 5, each of the first to third diffusion meta-lenses 131, 132 and 133 of the first lens layer 130 may include a nano pattern NP. The nano patterns NP of the first to third diffusion meta-lenses 131, 132 and 133 may each include a plurality of meta-atoms MAT.

Referring to FIG. 8 in addition to FIG. 5, the collimating meta-lens of the second lens layer 320 may include a nano pattern NP. The nano pattern of the collimating meta-lens of the second lens layer 320 may include a plurality of meta-atoms MAT.

The nano patterns NP included in the first to third diffusion meta-lenses 131, 132 and 133 of the first lens layer 130 may be arranged to be spaced and/or apart (e.g., spaced apart or separated) from one another. The nano pattern NP included in the first diffusion meta-lens 131 may overlap the first light source pixel SP1 and the first light emission area LA1, the nano pattern NP included in the second diffusion meta-lens 132 may overlap the second light source pixel SP2 and the second light emission area LA2, and the nano pattern NP included in the third diffusion meta-lens 133 may overlap the third light source pixel SP3 and the third light emission area LA3.

A width of the nano pattern NP included in the first diffusion meta-lens 131 may be greater than a width of the first light emission area LA1, a width of the nano pattern NP included in the second diffusion meta-lens 132 may be greater than a width of the second light emission area LA2, and a width of the nano pattern NP included in the third diffusion meta-lens 133 may be greater than a width of the third light emission area LA3.

In one or more embodiments, the size or area of the nano pattern NP included in the second lens layer 320 may be larger than the size or area of the nano pattern NP included in the first lens layer 130.

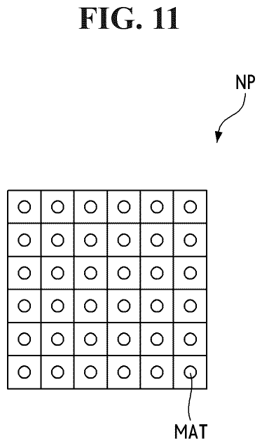

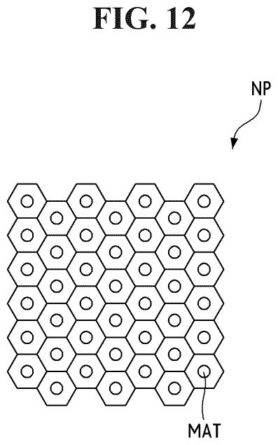

As shown in FIG. 7, a shape of the nano patterns NP included in each of the first to third diffusion meta-lenses 131, 132 and 133 of the first lens layer 130 may be circular on a plane (e.g., generally circular on a plane as shown, for example, in FIG. 7), but the present disclosure is not limited thereto. As shown in FIG. 8, a shape of the nano pattern NP included in the collimating meta-lens of the second lens layer 320 may be a square on a plane, but the present disclosure is not limited thereto. The shapes of the nano patterns NP of the first lens layer 130 and the second lens layer 320 will be described in more detail later with reference to FIGS. 11 and 12.

Diameters of the meta-atoms MAT included in the first lens layer 130 and the second lens layer 320 may range from about several tens of nanometers (nm) to several hundreds of nanometers. For example, the diameters of the meta-atoms MAT may range from 10 nm to 500 nm. In the present disclosure, when meta-atoms are circular, “diameter” indicates a diameter or an average diameter, and when the meta-atoms are non-spherical, the “diameter” indicates a major axis length or an average major axis length.

In one or more embodiments, the diameters of the meta-atoms MAT included in the first to third diffusion meta-lenses 131, 132 and 133 may be different from each other. For example, the diameter of the meta-atoms MAT included in the first diffusion meta-lens 131 may be greater than the diameter of the meta-atoms MAT included in the second diffusion meta-lens 132, and the diameter of the meta-atoms MAT included in the second diffusion meta-lens 132 may be greater than the diameter of the meta-atoms MAT included in the third diffusion meta-lens 133.

In one or more embodiments, the diameters of the meta-atoms MAT respectively included in the first to third diffusion meta-lenses 131, 132 and 133 may range from ¼ to ½ of a wavelength of light emitted from each of the first to third laser elements 120_1, 120_2 and 120_3. For example, because the first laser element 120_1 emits red light of which the main peak wavelength is included in a wavelength band of approximately 600 nm to 750 nm, the diameter of the meta-atoms MAT included in the first diffusion meta-lens 131 may be approximately 150 nm to 375 nm. Because the second laser element 120_2 emits green light of which the main peak wavelength is included in a wavelength band of approximately 480 nm to 560 nm, the diameter of the meta-atoms included in the second diffusion meta-lens 132 may be approximately 120 nm to 280 nm. Because the third laser element 120_3 emits blue light of which the main peak wavelength is included in a wavelength band of approximately 370 nm to 460 nm, the diameter of the meta-atoms MAT included in the third diffusion meta-lens 133 may be approximately 90 nm to 230 nm.

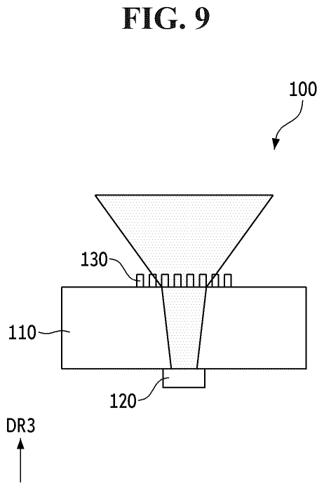

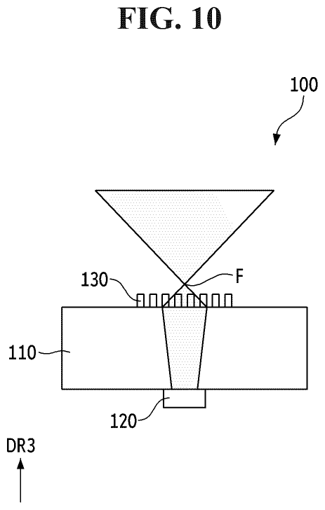

FIG. 9 is a schematic view illustrating a path of light emitted from a light source layer according to one or more embodiments of the present disclosure. FIG. 10 is a schematic view illustrating a path of light emitted from a light source layer according to one or more embodiments of the present disclosure.

Referring to FIGS. 9 and 10 in addition to FIG. 5, light emitted from the light source layer 120 may reach the first lens layer 130 by passing through the transparent first substrate 110. A portion of the light emitted from the light source layer 120 may move in the third direction DR3, and the other portion thereof may move while being diffused by being inclined at a certain angle in the third direction DR3. Therefore, as described above, the widths W1, W2 and W3 of the first to third diffusion meta-lenses 131, 132 and 133 of the first lens layer 130 may be greater than the widths of the first to third light emission areas LA1, LA2 and LA3.

In one or more embodiments, as shown in FIG. 9, the light which has reached the first lens layer 130 may be diffused by the nano pattern of the first lens layer 130. For example, the light emitted from the light source layer 120 may be diffused by the nano pattern of the first lens layer 130 at an angle wider than an initial diffusion angle. In such embodiments, each of the first to third diffusion meta-lenses 131, 132 and 133 of the first lens layer 130 may be a diffusion type (kind) lens.

In one or more embodiments, as shown in FIG. 10, the light which has reached the first lens layer 130 may be converged by the nano pattern of the first lens layer 130. For example, the light emitted from the light source layer 120 may be converged to a focal point F by the nano pattern of the first lens layer 130. The light passing through the focal point F may be diffused at an angle wider than the initial diffusion angle. In such embodiments, each of the first to third diffusion meta-lenses 131, 132 and 133 of the first lens layer 130 may be a convergent lens.

FIG. 11 is a plan view illustrating a nano pattern according to one or more embodiments of the present disclosure. FIG. 12 is a plan view illustrating a nano pattern according to one or more embodiments of the present disclosure.

Referring to FIGS. 11 and 12 in addition to FIGS. 5, 7 and 8, the meta-atoms MAT of the nano pattern NP included in the first lens layer 130 and the second lens layer 320 may be arranged in one or more suitable structures.

As an example, as shown in FIG. 11, the meta-atoms MAT may be arranged in the nano pattern NP in a square shape in a matrix (e.g., a matrix along the first and second directions DR1, DR2). For example, the meta-atoms MAT adjacent to each other in the matrix may be connected to each other to form a square shape.

As another example, as shown in FIG. 12, the meta-atoms MAT may be arranged in the nano pattern NP in a hexagonal shape. For example, there may be six meta-atoms MAT adjacent to any one meta-atom MAT, and the six meta-atoms MAT may be connected to one another to form a hexagonal shape.

The meta-atoms MAT of the nano pattern NP included in the first lens layer 130 and the second lens layer 320 may have one or more suitable shapes. For example, as shown in FIGS. 11 and 12, each of the meta-atoms MAT may have a circular shape (e.g., a generally circular shape) on a plane, but the present disclosure is not limited thereto. Each of the meta-atoms MAT may be provided in a square shape, a square shape with rounded corners, a hexagonal shape, another polygonal shape or a (e.g., any suitable) combination thereof.

The shape and arrangement of the meta-atoms MAT of the nano pattern NP are not limited to those shown in FIGS. 11 and 12.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The holographic display, electronic apparatus, devices for manufacturing the holographic device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A holographic display comprising:
a first substrate;
a first lens layer on a surface of the first substrate;
a light source layer on another surface of the first substrate;
a second substrate on the first lens layer;
a light modulation element on a surface of the second substrate; and
a second lens layer on another surface of the second substrate,
wherein each of the first lens layer and the second lens layer comprises a meta-lens.

2. The holographic display of claim 1, wherein
the light source layer comprises first to third laser elements spaced from one other, and
the first lens layer comprises first to third diffusion meta-lenses that overlap the first to third laser elements, respectively.

3. The holographic display of claim 2, wherein
the first to third laser elements respectively comprise first to third light emission areas through which light is to be emitted, and
a width of each of the first to third diffusion meta-lenses is larger than a width of each of the first to third light emission areas.

4. The holographic display of claim 2, wherein the first to third diffusion meta-lenses are configured to diffuse incident light.

5. The holographic display of claim 4, wherein the first to third diffusion meta-lenses comprise a diffusion-type lens.

6. The holographic display of claim 4, wherein each of the first to third diffusion meta-lenses comprise a convergent lens.

7. The holographic display of claim 4, wherein
the second lens layer comprises a collimation meta-lens, and
the collimation meta-lens is configured to convert incident light into parallel light.

8. The holographic display of claim 1, wherein
the light source layer comprises at least one laser element, and
the laser element is a vertical cavity surface emitting laser (VCSEL).

9. The holographic display of claim 8, wherein the laser element comprises:
a first electrode on the other surface of the first substrate;
a first reflective layer on the first electrode;
an opening layer on the first reflective layer;
an active layer on the opening layer;
a second reflective layer on the active layer; and
a second electrode on the second reflective layer.

10. The holographic display of claim 9, wherein
the laser element further comprises a passivation layer on the second electrode, the passivation layer defining an opening exposing at least a portion of a lower surface of the second electrode, and
the light source layer further comprises a reflective electrode covering the laser element, the reflective electrode being on the passivation layer.

11. The holographic display of claim 9, wherein
the at least one laser element comprises a first laser element, a second laser element and a third laser element, and
the first electrode is commonly located over the first to third laser elements.

12. The holographic display of claim 1, wherein the light modulation element comprises a circuit layer, a liquid crystal element layer on the circuit layer, and a color filter layer on the liquid crystal element layer.

13. The holographic display of claim 1, wherein
the first lens layer is configured to diffuse light passing through the first lens layer, and
the second lens layer is configured to convert the diffused light passing through the second lens layer into parallel light.

14. A holographic display comprising:
a light source panel comprising a light source layer and a first lens layer on the light source layer; and
a spatial light modulator on the light source panel, the spatial light modulator comprising a second lens layer and a light modulation element on the second lens layer,
wherein each of the first lens layer and the second lens layer comprises a meta-lens.

15. The holographic display of claim 14, wherein
the light source panel comprises one or more light source pixels to emit light,
the spatial light modulator comprises a plurality of light modulation pixels to modulate a phase of light, and
the number of the light modulation pixels is greater than the number of the light source pixels.

16. The holographic display of claim 15, wherein
the light source pixels comprise first to third light source pixels, and
the first to third light source pixels are configured to emit light incident on all of the light modulation pixels.

17. The holographic display of claim 14, wherein a size of the light source panel is smaller than a size of the spatial light modulator.

18. The holographic display of claim 14, further comprising:
a sealing portion sealing a space between the light source panel and the spatial light modulator; and
a gap defined by the light source panel, the spatial light modulator and the sealing portion,
wherein the first lens layer and the second lens layer are in the gap.

19. The holographic display of claim 18, wherein a height of the gap is in a range of 5 mm to 20 mm.

20. The holographic display of claim 14, wherein a size of the meta-lens of the first lens layer is smaller than a size of the meta-lens of the second lens layer.

21. An electronic device comprising:
a holographic device comprising:
a first substrate;
a first lens layer on one surface of the first substrate;
a light source layer on an opposite surface of the first substrate;
a second substrate on the first lens layer;
a light modulation element on one surface of the second substrate; and
a second lens layer on an opposite surface of the second substrate,
wherein each of the first lens layer and the second lens layer comprises a meta-lens.

22. The electronic device of claim 21, wherein
the light source layer comprises first to third laser elements spaced from each other, and
the first lens layer comprises first to third diffusion meta-lenses that overlap the first to third laser elements, respectively.

23. The electronic device of claim 22, wherein
the first to third laser elements respectively comprise first to third light emission areas through which light is to be emitted, and
a width of each of the first to third diffusion meta-lenses is larger than a width of each of the first to third light emission areas.

24. The electronic device of claim 22, wherein the first to third diffusion meta-lenses are configured to diffuse incident light.

25. The electronic device of claim 21, wherein
the second lens layer comprises a collimation meta-lens, and
the collimation meta-lens is configured to convert incident light into parallel light.

26. The electronic device of claim 21, wherein the electronic device comprises a mobile phone, a smartphone, a tablet personal computer, a mobile communication terminal, an electronic notebook, an e-book, a portable multimedia player, a navigation system, an ultramobile personal computer, a television, a laptop, a monitor, a billboard, a smart watch, a watch phone, or a car display.
